(19) United States
(12) Patent Application Publication
(10) Pub. No.: US 2017/0186701 A1
(43) Pub. Date: Jun. 29, 2017

(54) CRACK RESISTANT ELECTRONIC DEVICE PACKAGE SUBSTRATES

(71) Applicant: Intel Corporation, Santa Clara, CA (US)

(72) Inventors: Yuhong Cai, Folsom, CA (US); Sireesha Gogineni, Folsom, CA (US); John Yap, Folsom, CA (US)

(73) Assignee: Intel Corporation, Santa Clara, CA (US)

(21) Appl. No.: 14/998,229

(22) Filed: Dec. 26, 2015

(51) Int. Cl. H01L 23/00; H05K 1/11; H01L 21/48; H01L 23/498

(52) U.S. Cl. CPC H01L 23/562; H01L 23/49838; H01L 23/49822; H01L 23/49894; H05K 1/111; H01L 21/4857

(57) ABSTRACT

Crack resistant electronic device package substrate technology is disclosed. In an example, an electronic device package substrate can include a substrate core material having a surface. The substrate can also include a solder ball pad coupled to the surface of the substrate. In addition, the substrate can include a layer of solder resist material coupled to the surface of the substrate at a location that leaves a gap in between a lateral side of the solder ball pad and the solder resist material.

### TECHNICAL FIELD

Embodiments described herein relate generally to electronic device packages.

### BACKGROUND

Electronic device packages are widely used in many electronic products and computing systems. Such a package includes different parts, for example, substrates, dies, circuit traces, interconnects, encapsulation layers, electromagnetic interference (EMI) shielding, and solder ball grid arrays (BGA) among others. Because these parts include a wide variety of materials with different coefficients of thermal expansion (CTE), the impact of thermal forces thereon can cause performance failure.

### BRIEF DESCRIPTION OF THE DRAWINGS

Invention features and advantages will be apparent from the detailed description which follows, taken in conjunction with the accompanying drawings, which together illustrate, by way of example, various invention embodiments; and, wherein:

FIG. 1 illustrates an exemplary electronic device system;

FIG. 2 illustrates a bottom view of a substrate of an exemplary electronic device system; and

FIG. 3 illustrates an exemplary computing system.

Reference will now be made to the exemplary embodiments illustrated, and specific language will be used herein to describe the same. It will nevertheless be understood that no limitation of the scope or to specific invention embodiments is thereby intended.

### DESCRIPTION OF EMBODIMENTS

Before invention embodiments are disclosed and described, it is to be understood that no limitation to the particular structures, process steps, or materials disclosed herein is intended, but also includes equivalents thereof as would be recognized by those ordinarily skilled in the relevant arts. It should also be understood that terminology employed herein is used for describing particular examples only and is not intended to be limiting. The same reference numerals in different drawings represent the same element. Numbers provided in flow charts and processes are provided for clarity in illustrating steps and operations and do not necessarily indicate a particular order or sequence. Unless defined otherwise, all technical and scientific terms used herein have the same meaning as commonly understood by one of ordinary skill in the art to which this disclosure belongs.

As used in this specification and the appended claims, the singular forms “a,” “an” and “the” include plural referents unless the context clearly dictates otherwise. Thus, for example, reference to “a substrate” includes a plurality of such substrates.

In this disclosure, “comprises,” “comprising,” “containing” and “having” and the like can have the meaning ascribed to them in U.S. patent law and can mean “includes,” “including,” and the like, and are generally interpreted to be open ended terms. The terms “consisting of” or “consists of” are closed terms, and include only the components, structures, steps, or the like specifically listed in conjunction with such terms, as well as that which is in accordance with U.S. patent law. “Consisting essentially of” or “consists essentially of” have the meaning generally ascribed to them by U.S. patent law. In particular, such terms are generally closed terms, with the exception of allowing inclusion of additional items, materials, components, steps, or elements, that do not materially affect the basic and novel characteristics or function of the item(s) used in connection therewith. For example, trace elements present in a composition, but not affecting the composition's nature or characteristics would be permissible if present under the “consisting essentially of” language, even though not expressly recited in a list of items following such terminology. When using an open ended term, like “comprising” or “including,” in this specification, it is understood that direct support should be afforded also to “consisting essentially of” language as well as “consisting of” language as if stated explicitly and vice versa.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments described herein are, for example, capable of operation in other orientations than those illustrated or otherwise described herein. The term “coupled,” as used herein, is defined as directly or indirectly connected in an electrical or nonelectrical manner. Objects described herein as being “adjacent to” each other may be in physical contact with each other, in close proximity to each other, or in the same general region or area as each other, as appropriate for the context in which the phrase is used. Occurrences of the phrase “in one embodiment,” or “in one aspect,” herein do not necessarily all refer to the same embodiment or aspect.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of” particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, the term “about” is used to provide flexibility to a numerical range endpoint by providing that a given value may be “a little above” or “a little below” the endpoint.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 2, 3, 4, and 5, individually.

This same principle applies to ranges reciting only one numerical value as a minimum or a maximum. Furthermore, such an interpretation should apply regardless of the breadth of the range or the characteristics being described.

Reference throughout this specification to “an example” means that a particular feature, structure, or characteristic described in connection with the example is included in at least one embodiment. Thus, appearances of the phrases “in an example” in various places throughout this specification are not necessarily all referring to the same embodiment.

### EXAMPLE EMBODIMENTS

An initial overview of technology embodiments is provided below and specific technology embodiments are then described in further detail. This initial summary is intended to aid readers in understanding the technology more quickly but is not intended to identify key or essential features of the technology nor is it intended to limit the scope of the claimed subject matter.

A conventional BGA configuration has a solder ball pad, a solder resist material, and a substrate core material in contact at a single location called a “triple point.” Solder resist material typically has a much higher coefficient of thermal expansion (CTE) value compared to the solder ball pad and substrate core materials. Due to CTE mismatch between these three materials, differential thermal expansion of the materials during thermal cycling can lead to increased stresses in thin substrates. The triple point has a high stress concentration due to material discontinuity and is a potential crack initiation site. These cracks further propagate into the substrate during thermal cycling due to package stresses. Crack propagation in the substrate can lead to a crack in a trace in or on the substrate, which can cause an electrical failure of the package.

Certain invention embodiments provide an electronic device package substrate that is resistant to crack initiation and propagation, particularly cracks resulting from thermal cycling. The electronic device package substrate can include a substrate core material having a surface. The substrate can also include a solder ball pad coupled to the surface of the substrate. In addition, the substrate can include a layer of solder resist material coupled to the surface of the substrate at a location that leaves a gap in between a lateral side of the solder ball pad and the solder resist material. Thus, compared to a conventional BGA configuration, the triple point has been eliminated from a high stress region by the gap between the lateral side of the solder ball pad and the solder resist material. This can effectively eliminate the crack initiation point of the conventional BGA configuration and therefore improve substrate reliability margin. The gap between the lateral side of the solder ball pad and the solder resist material can be created with the same technique and processing step as conventional solder ball pad BGA openings with no additional process needed, therefore providing a cost effective solution.

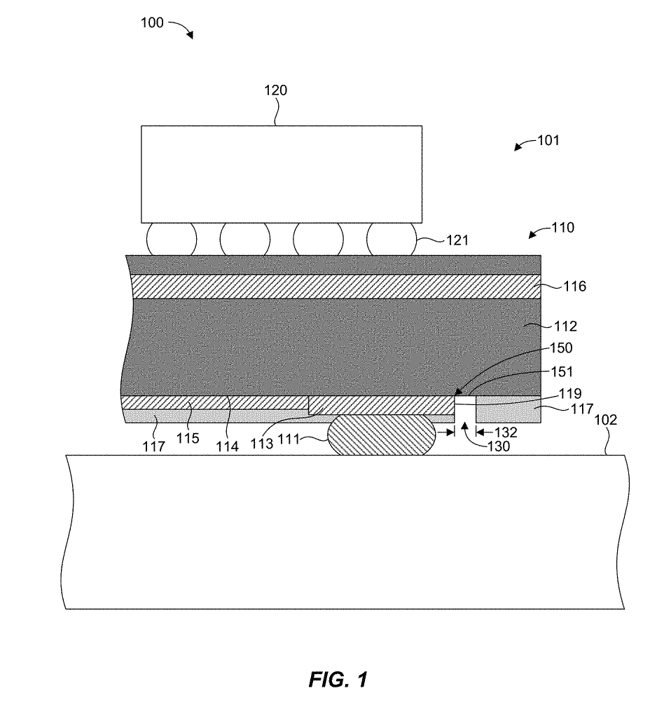

Referring to FIG. 1, an exemplary electronic device system 100 is illustrated. The system 100 can include an electronic device package 101 mounted on a motherboard 102 or other suitable substrate. The electronic device package 101 can be any type of electronic device package, such as a memory or a processor package. The electronic device package 101 can include a substrate 110 and an electronic component 120 (e.g. a die) mounted on the substrate 110. The electronic component 120 can be coupled to the substrate 110 in any suitable manner, such as with a die attach material, C4 bumps 121 (e.g. copper), and/or an epoxy underfill. The electronic device package 101 can include any component or feature that may be suitable for an electronic device package. For example, the electronic component 120 can be encapsulated by epoxy (not shown), and/or the electronic device package can include electromagnetic interference (EMI) shielding (not shown) for the electronic component 120. The electronic device package 101 can be coupled to the motherboard 102 via one or more solder balls 111, which may be arranged in a ball grid array and configured to electrically couple with traces (not shown) on the motherboard 102.

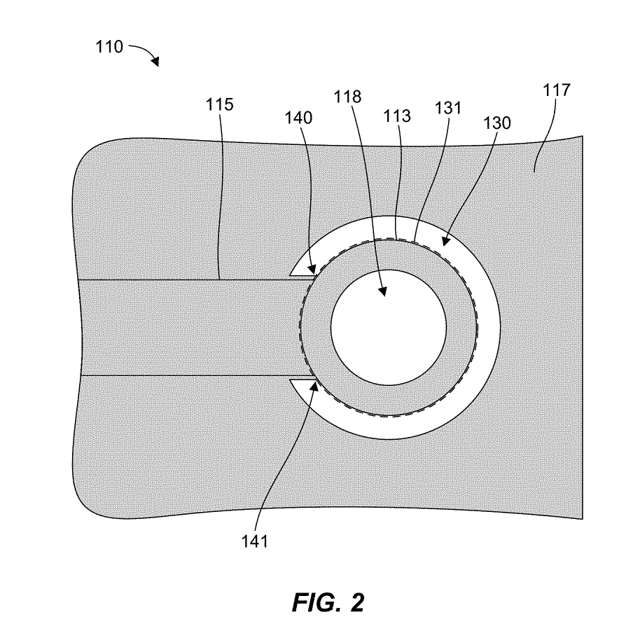

With continued reference to FIG. 1 and further reference to FIG. 2 a bottom view of the substrate 110 is shown with the solder ball 111 omitted. The substrate 110 can include a substrate core 112. The substrate 110 can also include a solder ball pad 113 coupled to the substrate core 112, such as at a surface 114 of the substrate core 112. An electrically conductive metal (e.g., copper) trace 115 can be coupled to the solder ball pad 113 and can extend from the solder ball pad 113 along the surface 114 of the substrate core 112. In addition, an electrically conductive metal trace 116 can be disposed at least partially within the substrate core 112.

The substrate 110 can also include a layer 117 of solder resist material or a solder mask. The layer 117 of solder resist material can cover a portion of the solder ball pad 113 and can be configured to expose a portion 118 of the solder ball pad 113 so that the solder ball pad 113 can receive and couple with the solder ball 111. The layer 117 of solder resist material can maintain the solder ball 111 on the solder ball pad 113 and prevent unwanted flow of the solder ball 111 onto other components or features associated with the substrate 110 and/or the motherboard 102. The layer 117 of solder resist can also cover at least a portion of the metal trace 115. In general, the layer 117 of solder resist can cover any portion of the substrate 110, such as to provide protection for various components of the substrate 110. For example, the layer 117 of solder resist can be applied over electrically conductive metal traces and solder ball pads of the substrate 110 for protection against oxidation and to prevent solder bridges from forming between closely spaced solder ball pads.

Any suitable material may be utilized to form the substrate core 112. Typically, the substrate core 112 will be made of a material that includes a resin and/or a fiber for strength. The substrate core 112 material will typically have a CTE of less than about 20 μm/m/° C., with a CTE from about 8 μm/m/° C. to about 15 μm/m/° C. being common.

Any suitable material may be utilized to form the solder ball pad 113. The solder ball pad 113 will typically be made of a material that comprises a metal, such as an electrically conductive metal. Such metals may have a CTE of from about 16 μm/m/° C. to about 18 μm/m/° C.

Any suitable material may be utilized to form the layer 117 of solder resist. The solder resist material commonly comprises a polymer and has a coefficient of thermal expansion of from about 30 μm/m/° C. to about 60 μm/m/° C.

With the solder ball pad 113 and the trace 115 coupled to the surface 114 of the substrate core 112, and the layer 117 of solder resist material disposed over the surface 114 of the substrate core 112 and at least portions of the solder ball pad 113 and the trace 115, there exists the potential for three different materials to meet at a common location (indicated at 150) on the substrate 110, which would form a triple point. As mentioned above, the three different materials (the substrate core material, the solder ball pad material, and the solder resist material) can have different CTEs. Such a triple point location, which is common on conventional BGA packages, could be instrumental in initiating and propagating cracks through one or more materials of the substrate 110 due to differential thermal expansion of the different materials when subjected to thermal cycles during normal operating conditions. In addition to thermal stress created by differential thermal expansion, external mechanical loading (e.g., forces and/or moments) from the motherboard 102 can be transferred to the substrate 110 via the solder ball 111 connection, which can cause additional stress in the substrate 110. The resulting combination of thermal stress and mechanical stress can initiate or cause a crack to form at a triple point location, and can cause the crack to propagate through a material, which can ultimately lead to failure of a substrate component. For example, such a crack could propagate through the substrate core 112 material to the trace 116, which can cause the trace 116 to break, leading to an electrical disconnect or failure.

To minimize the likelihood of crack formation and propagation in the substrate 110, the substrate can be constructed with a space or gap 130 between a lateral side 119 of the solder ball pad 113 material and another material, such as the solder resist material. Thus, the layer 117 of solder resist material can be coupled to the surface 114 at a location that leaves the space or gap 130 in between the lateral side 119 of the solder ball pad 113 and the solder resist material. The junction (indicated at 150) of the solder ball pad 113 and the substrate core 112 can therefore be limited to two materials by the space or gap 130 to the solder resist material. The two materials in contact about the perimeter 131 or lateral side or edge of the solder ball pad 113 (the substrate core material and the solder ball pad material) can have relatively similar CTEs compared to the third material (solder resist material), which is absent due to the space or gap 130 to the solder resist material. When combined with the stress due to external loading from the motherboard 102, the thermal stress due to these relatively similar CTE materials will typically not be sufficient to initiate a crack in the substrate core 112. In one aspect, the space or gap 130 can extend about at least a portion of a perimeter 131 of the solder ball pad 113 material, as shown in FIG. 2. The absence of a triple point about at least a portion of the solder ball pad 113 can reduce the number of crack initiation points and therefore minimize or reduce the impact of differential thermal expansion on the substrate 110.

In one aspect, shown in FIG. 2, the space or gap 130 can terminate proximate to the trace 115 such that the trace 115 is covered in the layer 117 of solder resist material. In this case, a triple point involving the solder ball pad 113 material may exist at a small location proximate the trace 115, indicated at 140, 141. To minimize the impact of such a triple point 140, 141, the trace 115 can be routed to extend from the solder ball pad 113 at a relatively low stress location, such as away from an edge or side of the substrate 110. In other words, the trace 115 and thus the triple point 140, 141 can be located about the solder ball pad 113 and oriented to avoid high stress due to the external mechanical loading from the coupling with the motherboard 102, as a crack will typically form at a location of the highest stress. Thus, a crack initiation point or location can effectively be eliminated by the presence of the space or gap 130. In addition, the size of the triple point location can be minimized to reduce the impact of the triple point, such as by minimizing the amount of solder resist material about the sides of the trace 115. The substrate 110 can therefore be rendered crack resistant by the principles disclosed herein.

The space or gap 130 can be of any suitable size, shape, or dimension such that a triple point is avoided to the extent possible within practical limits. For example, the gap or space 130 can have a dimension 132 from the lateral side 119 of the solder ball pad 113 of less than about 50 μm, which may be dictated by solder ball pad 113 size, pitch, and manufacturer tolerances. A practical minimum dimension 132 of the gap or space 130 may be 20 μm to ensure no contact between the solder ball pad 113 and the solder resist material at high temperatures, although the dimension 132 may be smaller. A typical range for the dimension 132 of the gap or space 130 may be from about 35 μm to about 50 μm based on current substrate photolithography capability, although this range is not meant to be limiting.

The substrate 110 can be constructed utilizing any suitable technique or process. In one aspect, the substrate 110 can be formed by disposing the layer 117 of solder resist material on the surface 114 of the substrate core 112 material. The layer 117 of solder resist material can be formed by laminating, spraying, silk screening, and/or any other suitable photolithographic technique. For example, the solder resist material can be an epoxy liquid that is silkscreened through a pattern onto the surface 114 of the substrate core 112, the trace 115, and the solder ball pad 113. In another example, liquid photoimageable solder mask (LPSM) ink can be silkscreened or sprayed onto the surface 114 of the substrate core 112, the trace 115, and the solder ball pad 113, then exposed to a pattern and developed to provide openings in the pattern. In yet another example, dry film photoimageable solder mask (DFSM) can be vacuum laminated onto the surface 114 of the substrate core 112, the trace 115, and the solder ball pad 113, then exposed to a pattern and developed to provide openings in the pattern. The solder resist material is typically thermally cured after the pattern is defined for the above examples.

The space or gap 130 can therefore be formed between the lateral side 119 of the solder ball pad 113 and the solder resist material using photolithographic techniques to mask the solder resist material, such as about at least a portion of the perimeter 131 of the solder ball pad 113. Such techniques can also be used to expose the substrate core 112 material (e.g., a portion of the surface 114 indicated at 151) between the lateral side 119 of the solder ball pad 112 and solder resist material to create the gap or space 130, as well as to expose the portion 118 of the solder ball pad 113. The substrate 110 can therefore be formed utilizing current techniques and practices. For example, a portion of a solder ball pad may be exposed to receive a solder ball utilizing photolithographic techniques to construct a typical substrate. The gap or space 130 of the substrate 110 can be formed at the same time as the exposed portion 118 of the solder ball pad 113 utilizing the same technique with no additional processing needed, thus representing a minimal impact to current production practices. Formation of the gap or space 130 can therefore be cost effective and easy to implement while providing the benefit of reduced CTE mismatch at the side 119 or edge of the solder ball pad 113 proximate the substrate core 112, which can minimize the potential for crack initiation and thereby improve reliability of the substrate 110.

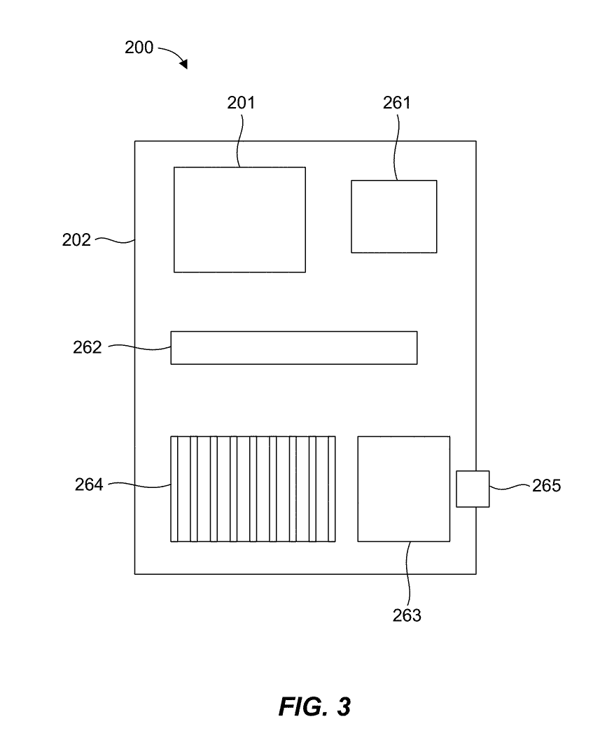

FIG. 3 illustrates a computing system 200 in accordance with an example of the present disclosure. The computing system 200 can be a type of electronic device system as discussed above with reference to FIG. 1. The computing system 200 can include an electronic device package 201 as disclosed herein, mounted on a motherboard 202. In one aspect, the computing system 200 can also include a processor 261, a memory device 262, a radio 263, a heat sink 264, a port 265, a slot, or any other suitable device, which can be operably coupled to the motherboard 202. The computing system 200 can comprise any type of computing system, such as a desktop computer, a laptop computer, a tablet computer, a smartphone, a server, etc.

### Examples

The following examples pertain to further embodiments.

In one example there is provided, an electronic device package substrate comprising a substrate core material having a first surface, a solder ball pad coupled to the first surface, and a layer of solder resist material coupled to the first surface at a location that leaves a gap in between a lateral side of the solder ball pad and the solder resist material.

In one example of an electronic device package substrate, the gap extends about at least a portion of a perimeter of the solder ball pad.

In one example of an electronic device package substrate, the gap is less than about 50 μm.

In one example of an electronic device package substrate, the layer of solder resist material covers a portion of the solder ball pad, and wherein an exposed portion of the solder ball pad is configured to receive a solder ball.

In one example of an electronic device package substrate, the electronic device package substrate can further comprise a metal trace coupled to the solder ball pad and extending therefrom.

In one example of an electronic device package substrate, the metal trace extends along the first surface of the substrate core material.

In one example of an electronic device package substrate, the layer of solder resist covers at least a portion of the metal trace.

In one example of an electronic device package substrate, the electronic device package substrate can further comprise a metal trace disposed at least partially within the substrate core material.

In one example of an electronic device package substrate, the substrate core material comprises a resin.

In one example of an electronic device package substrate, the substrate core material comprises a fiber.

In one example of an electronic device package substrate, the substrate core material has a coefficient of thermal expansion of less than about 20 μm/m/° C.

In one example of an electronic device package substrate, the solder ball pad comprises a metal material.

In one example of an electronic device package substrate, the solder ball pad comprises a material having a coefficient of thermal expansion of from about 16 μm/m/° C. to about 18 μm/m/° C.

In one example of an electronic device package substrate, the solder resist material comprises a polymer.

In one example of an electronic device package substrate, the solder resist material has a coefficient of thermal expansion of from about 30 μm/m/° C. to about 60 μm/m/° C.

In one example there is provided, an electronic device package comprising a substrate having a substrate core material, a solder ball pad material coupled thereto, and a layer of solder resist material. A space can be located between a lateral side of the solder ball pad material and another material. The electronic device package can also comprise a solder ball coupled to the solder ball pad material, and an electronic component mounted on the substrate.

In one example of an electronic device package, the space is between the lateral side of the solder ball pad material and the solder resist material.

In one example of an electronic device package, the space extends about at least a portion of a perimeter of the solder ball pad material.

In one example of an electronic device package, the space is less than about 50 μm.

In one example of an electronic device package, the layer of solder resist material covers a portion of the solder ball pad material, and wherein an exposed portion of the solder ball pad material is configured to receive the solder ball.

In one example of an electronic device package, the electronic device package can further comprise a metal trace coupled to the solder ball pad material and extending therefrom.

In one example of an electronic device package, the metal trace extends along a surface of the substrate core material.

In one example of an electronic device package, the layer of solder resist covers at least a portion of the metal trace.

In one example of an electronic device package, the electronic device package can further comprise a metal trace disposed at least partially within the substrate core material.

In one example of an electronic device package, the substrate core material comprises a resin.

In one example of an electronic device package, the substrate core material comprises a fiber.

In one example of an electronic device package, the substrate core material has a coefficient of thermal expansion of less than about 20 μm/m/° C.

In one example of an electronic device package, the solder ball pad material comprises a metal.

In one example of an electronic device package, the solder ball pad material has a coefficient of thermal expansion of from about 16 μm/m/° C. to about 18 μm/m/° C.

In one example of an electronic device package, the solder resist material comprises a polymer.

In one example of an electronic device package, the solder resist material has a coefficient of thermal expansion of from about 30 μm/m/° C. to about 60 μm/m/° C.

In one example of an electronic device package, a computing system can comprise a motherboard and an electronic device package as disclosed herein, mounted on the motherboard.

In one example of an electronic device package, the computing system can further comprise a processor, a memory device, a heat sink, a radio, a slot, a port, or a combination thereof operably coupled to the motherboard.

In one example of an electronic device package, the computing system comprises a desktop computer, a laptop computer, a tablet computer, a smartphone, a server, or a combination thereof.

In one example there is provided, a method of minimizing crack formation and propagation in an electronic device package substrate comprising obtaining a substrate core material with a solder ball pad coupled to a surface of the substrate core material, disposing a layer of solder resist material on the surface of the substrate core material, and forming a gap between a lateral side of the solder ball pad and the solder resist material.

In one example of a method of minimizing crack formation and propagation, the gap extends about at least a portion of a perimeter of the solder ball pad.

In one example of a method of minimizing crack formation and propagation, the gap is less than about 50 μm.

In one example of a method of minimizing crack formation and propagation, forming the gap comprises photolithographically masking the solder resist material.

In one example of a method of minimizing crack formation and propagation, forming the gap comprises masking about at least a portion of a perimeter of the solder ball pad.

In one example of a method of minimizing crack formation and propagation, the method further comprises exposing a portion of the solder ball pad to receive a solder ball.

In one example of a method of minimizing crack formation and propagation, disposing the layer of solder resist material on the surface of the substrate core material comprises laminating, spraying, silk screening, or a combination thereof.

In one example of a method of minimizing crack formation and propagation, a metal trace is coupled to the solder ball pad and extending therefrom.

In one example of a method of minimizing crack formation and propagation, the metal trace extends along the surface of the substrate core material.

In one example of a method of minimizing crack formation and propagation, the layer of solder resist covers at least a portion of the metal trace.

In one example of a method of minimizing crack formation and propagation, a metal trace is disposed at least partially within the substrate core material.

In one example of a method of minimizing crack formation and propagation, the substrate core material comprises a resin.

In one example of a method of minimizing crack formation and propagation, the substrate core material comprises a fiber.

In one example of a method of minimizing crack formation and propagation, the substrate core material has a coefficient of thermal expansion of less than about 20 μm/m/° C.

In one example of a method of minimizing crack formation and propagation, the solder ball pad comprises a metal material.

In one example of a method of minimizing crack formation and propagation, the solder ball pad comprises a material having a coefficient of thermal expansion of from about 16 μm/m/° C. to about 18 μm/m/° C.

In one example of a method of minimizing crack formation and propagation, the solder resist material comprises a polymer.

In one example of a method of minimizing crack formation and propagation, the solder resist material has a coefficient of thermal expansion of from about 30 μm/m/° C. to about 60 μm/m/° C.

In one example there is provided, a method of making an electronic device package substrate comprising coupling solder ball pad material to a surface of a substrate core material, disposing a layer of solder resist material on the surface of the substrate core material, and exposing the substrate core material between a lateral side of the solder ball pad material and another material to create a gap.

In one example of a method of making an electronic device package, the gap is between the lateral side of the solder ball pad material and the solder resist material.

In one example of a method of making an electronic device package substrate, the gap extends about at least a portion of a perimeter of the solder ball pad material.

In one example of a method of making an electronic device package substrate, the gap is less than about 50 μm.

In one example of a method of making an electronic device package substrate, exposing the substrate comprises photolithographically masking the solder resist material.

In one example of a method of making an electronic device package substrate, exposing the substrate comprises masking about at least a portion of a perimeter of the solder ball pad material.

In one example of a method of making an electronic device package substrate, the method further comprises exposing a portion of the solder ball pad material to receive a solder ball.

In one example of a method of making an electronic device package substrate; disposing the layer of solder resist material on the surface of the substrate core material comprises laminating, spraying, silk screening, or a combination thereof.

In one example of a method of making an electronic device package substrate, a metal trace is coupled to the solder ball pad material and extending therefrom.

In one example of a method of making an electronic device package substrate, the metal trace extends along the surface of the substrate core material.

In one example of a method of making an electronic device package substrate, the layer of solder resist covers at least a portion of the metal trace.

In one example of a method of making an electronic device package substrate, a metal trace is disposed at least partially within the substrate core material.

In one example of a method of making an electronic device package substrate, the substrate core material comprises a resin.

In one example of a method of making an electronic device package substrate, the substrate core material comprises a fiber.

In one example of a method of making an electronic device package substrate, the substrate core material has a coefficient of thermal expansion of less than about 20 μm/m/° C.

In one example of a method of making an electronic device package substrate, the solder ball pad material comprises a metal.

In one example of a method of making an electronic device package substrate, the solder ball pad material has a coefficient of thermal expansion of from about 16 μm/m/° C. to about 18 μm/m/° C.

In one example of a method of making an electronic device package substrate, the solder resist material comprises a polymer.

In one example of a method of making an electronic device package substrate, the solder resist material has a coefficient of thermal expansion of from about 30 μm/m/° C. to about 60 μm/m/° C.

In one example there is provided, a method of making an electronic device package can comprise obtaining a substrate having a substrate core material, a solder ball pad material coupled thereto, and a layer of solder resist material. A space can be located between a lateral side of the solder ball pad material and another material. The method can also comprise coupling a solder ball to the solder ball pad material.

In one example of making an electronic device package, the space is between the lateral side of the solder ball pad material and the solder resist material.

In one example of making an electronic device package, the space extends about at least a portion of a perimeter of the solder ball pad material.

In one example of making an electronic device package, the space is less than about 50 μm.

In one example of making an electronic device package, the layer of solder resist material covers a portion of the solder ball pad material, and wherein an exposed portion of the solder ball pad material is configured to receive the solder ball.

In one example of making an electronic device package, the method can further comprise a metal trace coupled to the solder ball pad material and extending therefrom.

In one example of making an electronic device package, the metal trace extends along a surface of the substrate core material.

In one example of making an electronic device package, the layer of solder resist covers at least a portion of the metal trace.

In one example of making an electronic device package, the method can further comprise a metal trace disposed at least partially within the substrate core material.

In one example of making an electronic device package, the substrate core material comprises a resin.

In one example of making an electronic device package, the substrate core material comprises a fiber.

In one example of making an electronic device package, the substrate core material has a coefficient of thermal expansion of less than about 20 μm/m/° C.

In one example of making an electronic device package, the solder ball pad material comprises a metal.

In one example of making an electronic device package, the solder ball pad material has a coefficient of thermal expansion of from about 16 μm/m/° C. to about 18 μm/m/° C.

In one example of making an electronic device package, the solder resist material comprises a polymer.

In one example of making an electronic device package, the solder resist material has a coefficient of thermal expansion of from about 30 μm/m/° C. to about 60 μm/m/° C.

Circuitry used in electronic components or devices (e.g. a die) of an electronic device package can include hardware, firmware, program code, executable code, computer instructions, and/or software. Electronic components and devices can include a non-transitory computer readable storage medium which can be a computer readable storage medium that does not include signal. In the case of program code execution on programmable computers, the computing devices recited herein may include a processor, a storage medium readable by the processor (including volatile and non-volatile memory and/or storage elements), at least one input device, and at least one output device. Volatile and non-volatile memory and/or storage elements may be a RAM, EPROM, flash drive, optical drive, magnetic hard drive, solid state drive, or other medium for storing electronic data. Node and wireless devices may also include a transceiver module, a counter module, a processing module, and/or a clock module or timer module. One or more programs that may implement or utilize any techniques described herein may use an application programming interface (API), reusable controls, and the like. Such programs may be implemented in a high level procedural or object oriented programming language to communicate with a computer system. However, the program(s) may be implemented in assembly or machine language, if desired. In any case, the language may be a compiled or interpreted language, and combined with hardware implementations.

Furthermore, the described features, structures, or characteristics may be combined in any suitable manner in one or more embodiments. In this description, numerous specific details are provided, such as examples of layouts, distances, network examples, etc. One skilled in the relevant art will recognize, however, that many variations are possible without one or more of the specific details, or with other methods, components, layouts, measurements, etc. In other instances, well-known structures, materials, or operations are not shown or described in detail but are considered well within the scope of the disclosure.

While the forgoing examples are illustrative of the specific embodiments in one or more particular applications, it will be apparent to those of ordinary skill in the art that numerous modifications in form, usage and details of implementation can be made without departing from the principles and concepts articulated herein. Accordingly, no limitation is intended thereby.

1. An electronic device package substrate, comprising:
a substrate core material having a first surface;
a solder ball pad coupled to the first surface; and
a layer of solder resist material coupled to the first surface at a location that leaves a gap in between a lateral side of the solder ball pad and the solder resist material, wherein a portion of the layer of solder resist material is disposed between an exposed surface of the solder ball pad and the gap.

2. The electronic device package substrate of claim 1, wherein the gap extends about at least a portion of a perimeter of the solder ball pad.

3. The electronic device package substrate of claim 1, wherein the gap is less than about 50 μm.

4. The electronic device package substrate of claim 1, wherein the layer of solder resist material covers a portion of the solder ball pad, and wherein an exposed portion of the solder ball pad is configured to receive a solder ball.

5. The electronic device package substrate of claim 1, further comprising a metal trace coupled to the solder ball pad and extending therefrom.

6. The electronic device package substrate of claim 1, further comprising a metal trace disposed at least partially within the substrate core material.

7. The electronic device package substrate of claim 1, wherein the substrate core material comprises a resin.

8. The electronic device package substrate of claim 1, wherein the substrate core material comprises a glass fiber.

9. The electronic device package substrate of claim 1, wherein the substrate core material has a coefficient of thermal expansion of less than about 20 μm/m/° C.

10. The electronic device package substrate of claim 1, wherein the solder ball pad comprises a metal material.

11. The electronic device package substrate of claim 1, wherein the solder ball pad comprises a material having a coefficient of thermal expansion of from about 16 μm/m/° C. to about 18 μm/m/° C.

12. The electronic device package substrate of claim 1, wherein the solder resist material comprises a polymer.

13. The electronic device package substrate of claim 1, wherein the solder resist material has a coefficient of thermal expansion of from about 30 μm/m/° C. to about 60 μm/m/° C.

14. A method of making an electronic device package substrate, comprising:
coupling solder ball pad material to a surface of a substrate core material;
disposing a layer of solder resist material on the surface of the substrate core material;
exposing the substrate core material between a lateral side of the solder ball pad material and another material to create a gap; and
exposing a surface of the solder ball pad such that a portion of the layer of solder resist material is disposed between the exposed surface of the solder ball pad and the gap.

15. The method of claim 14, wherein the gap is between the lateral side of the solder ball pad material and the solder resist material.

16. The method of claim 14, wherein the gap extends about at least a portion of a perimeter of the solder ball pad material.

17. The method of claim 14, wherein the gap is less than about 50 μm.

18. The method of claim 14, wherein exposing the substrate comprises photolithographic masking of the solder resist material.

19. The method of claim 14, wherein exposing the substrate comprises masking about at least a portion of a perimeter of the solder ball pad material.

20. The method of claim 14, further comprising exposing a portion of the solder ball pad material to receive a solder ball.

21. The method of claim 14, wherein disposing the layer of solder resist material on the surface of the substrate core material comprises laminating, spraying, silk screening, or a combination thereof.

22. The method of claim 14, wherein a metal trace is coupled to the solder ball pad material and extending therefrom.

23. The method of claim 14, wherein a metal trace is disposed at least partially within the substrate core material.

24. The method of claim 14, wherein the substrate core material has a coefficient of thermal expansion of less than about 20 μm/m/° C.

25. The method of claim 14, wherein the solder ball pad material has a coefficient of thermal expansion of from about 16 μm/m/° C. to about 18 μm/m/° C.

26. The method of claim 14, wherein the solder resist material has a coefficient of thermal expansion of from about 30 μm/m/° C. to about 60 μm/m/° C.
